(19) United States
(12) Patent Application Publication
(10) Pub. No.: US 2016/0234930 A1
(43) Pub. Date: Aug. 11, 2016

(54) STRETCHABLE TRANSPARENT ELECTRODE AND METHOD OF FABRICATING SAME

(71) Applicant: ELECTRONICS AND TELECOMMUNICATIONS RESEARCH INSTITUTE, Daejeon (KR)

(72) Inventors: Chan Woo PARK, Daejeon (KR); Jae Bon KOO, Daejeon (KR); Bock Soon NA, Daejeon (KR); Ji-Young OH, Daejeon (KR); Sang Seok LEE, Sejong (KR); Soon-Won JUNG, Daejeon (KR)

(73) Assignee: ELECTRONICS AND TELECOMMUNICATIONS RESEARCH INSTITUTE, Daejeon (KR)

(21) Appl. No.: 14/869,424

(22) Filed: Sep. 29, 2015

(30) Foreign Application Priority Data
Feb. 5, 2015 (KR) 10-2015-0018038

(51) Int. Cl. H05K 1/02; H05K 3/10; H05K 3/00; H05K 1/09; H05K 1/03

(52) U.S. Cl. CPC H05K 1/0283; H05K 1/09; H05K 1/03; H05K 3/007; H05K 3/0014; H05K 3/10; H05K 3/0023; H05K 3/0055; H05K 2203/0562; H05K 2203/0548; H05K 2201/0323; H05K 2201/0335; H05K 2201/0379; H05K 2201/0391; H05K 2201/0364; H05K 2201/0302

(57) ABSTRACT

Provided is a stretchable transparent electrode including a first substrate having an uneven surface, a first conductive film conformally covering the uneven surface of the first substrate to have an uneven top surface, a second conductive film conformally covering the first conductive film to have an uneven top surface, and a second substrate covering the second conductive film, wherein one of the first and second conductive films is a metal film and the other is a graphene film.

### CROSS-REFERENCE TO RELATED APPLICATION

This U.S. non-provisional patent application claims priority under 35 U.S.C. §119 of Korean Patent Application No. 10-2015-0018038, filed on Feb. 5, 2015, the entire contents of which are hereby incorporated by reference.

### BACKGROUND

The present disclosure herein relates to a stretchable transparent electrode and a method of fabricating the same.

A stretchable electronic device may still maintain an electrical function even when a substrate is expanded by a stress applied from an outside. The stretchable electronic device has a potential application in a variety of fields such as a robot sensor skin, a wearable communication device, a built/attached-in body type bio device, a next-generation display beyond a limitation of a simple bendable and/or flexible device.

The stretchable electronic device may include interconnections of a stretchable material having conductivity instead of a metal material. A conductive stretchable material mainly includes a conductive material such as a conductive polymer, carbon nanotube, and graphene. However, the conductive stretchable material may have a drawback of high electrical resistance compared to a metal material while having a high expansion ability.

### SUMMARY

The present disclosure provides a stretchable transparent electrode having more enhanced electrical conductivity.

The present disclosure also provides a method of fabricating a stretchable transparent electrode having more enhanced electrical conductivity.

The object of the present disclosure is not limited to the aforesaid, but other objects not described herein will be clearly understood by those skilled in the art from descriptions below.

An embodiment of the inventive concept provides a stretchable transparent electrode including a first substrate having an uneven surface, a first conductive film conformally covering the uneven surface of the first substrate to have an uneven top surface, a second conductive film conformally covering the first conductive film to have an uneven top surface, and a second substrate covering the second conductive film, wherein one of the first and second conductive films is a metal film and the other is a graphene film.

In an embodiment, the first conductive film may be a graphene film and the second conductive film may be a metal film.

In an embodiment, the first conductive film may be a metal film and the second conductive film may be a graphene film.

In an embodiment, a light may pass through the metal film.

In an embodiment, the metal film may include a crack.

In an embodiment, the stretchable transparent electrode may further include a third conductive film conformally covering the second conductive film, and the third conductive film may be a graphene film.

In an embodiment, the uneven surface of the first substrate may include convex portions and concave portions, and the convex portions and the concave portions may be alternately and repeatedly arranged in a first direction and may extend in a second direction crossing the first direction.

In an embodiment, the uneven surface of the first substrate may include convex portions and concave portions, and the convex portions and the concave portions may be alternately and repeatedly arranged in a first direction and in a second direction crossing the first direction.

In an embodiment, the first and second substrates may include polydimethylsiloxane PDMS or polyurethane.

In other embodiments of the inventive concept, a method of fabricating a stretchable transparent electrode, the method including forming a mold structure having an uneven surface, forming a polymer film on the uneven surface of the mold structure, separating the polymer film from the mold structure to form a first substrate having an uneven surface, conformally forming a graphene film on the uneven surface of the first substrate, and conformally forming a metal film on the graphene film.

In an embodiment, the method may further include forming a second substrate on the metal film, and the first and second substrates may include polydimethylsiloxane PDMS or polyurethane.

In an embodiment, the method may further include conformally forming a second graphene film on the metal film.

In an embodiment, the forming the mold structure may include preparing a mother substrate, patterning the mother substrate to form trenches, and forming a photoresist film filling the trenches on the mother substrate, and concave portions of the photoresist film may be formed on the trenches and convex portions of the photoresist film may be formed on projecting surfaces of the mother substrate due to a step difference between bottom surfaces of the trenches and projecting surfaces of the mother substrate disposed between the trenches.

In an embodiment, the forming the mold structure may include preparing a mother substrate, forming a photoresist film on the mother substrate, patterning the photoresist film to form a pattern including angled convex portions and angled concave portions, and performing a reflow process on the photoresist film to change the angled convex portions into rounded convex portions and the angled concave portions into rounded concave portions so as to form a photoresist film having an uneven surface.

In an embodiment, the forming the mold structure may include preparing a mother substrate, forming a photoresist film on the mother substrate, and forming the photoresist film curved in a round shape by using a gray scale photomask.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 illustrates a cross-sectional view of a transparent electrode according to a first embodiment of the present inventive concept;

FIG. 2 illustrates a cross-sectional view of a transparent electrode according to a second embodiment of the present inventive concept;

FIG. 3 illustrates a cross-sectional view of a transparent electrode according to a third embodiment of the present inventive concept;

FIG. 4 illustrates a cross-sectional view of a transparent electrode according to a fourth embodiment of the present inventive concept;

FIGS. 5A to 5D illustrate cross-sectional views of a method of fabricating a transparent electrode according to the first embodiment of the present inventive concept;

FIGS. 6A to 6C illustrate cross-sectional views of one example of a method of fabricating a mold structure;

FIGS. 7A to 7C illustrate cross-sectional views of another example of a method of fabricating a mold structure;

FIGS. 8A to 8C illustrate cross-sectional views of still another example of a method of fabricating a mold structure; and

FIGS. 9A and 9B illustrate perspective views of a curved surface according to an embodiment of the present inventive concept.

### DETAILED DESCRIPTION

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explaining a specific exemplary embodiment while not limiting the present invention. The terms of a singular form may include plural forms unless referred to the contrary. The meaning of “include,” “comprise,” “including,” or “comprising,” specifies mentioned components, steps, operations and/or elements but does not exclude other components, steps, operations and/or elements.

Additionally, the embodiment in the detailed description will be described with sectional views and/or plan views as ideal exemplary views of the present invention. In the figures, the dimensions of layers and regions are exaggerated for an effective description of technical content. As such, variations from the shapes of the illustrations as a result, for example, of manufacturing techniques and/or tolerances, are to be expected. Therefore, the embodiments of the present invention are not limited to the specific shape illustrated in the exemplary views, but may include other shapes that may be created according to manufacturing processes. For example, an etched region illustrated as a right angle may have rounded or curved features. Areas exemplified in the drawings have general properties, and are used to illustrate a specific shape of a device region. Thus, this should not be construed as limited to the scope of the present invention.

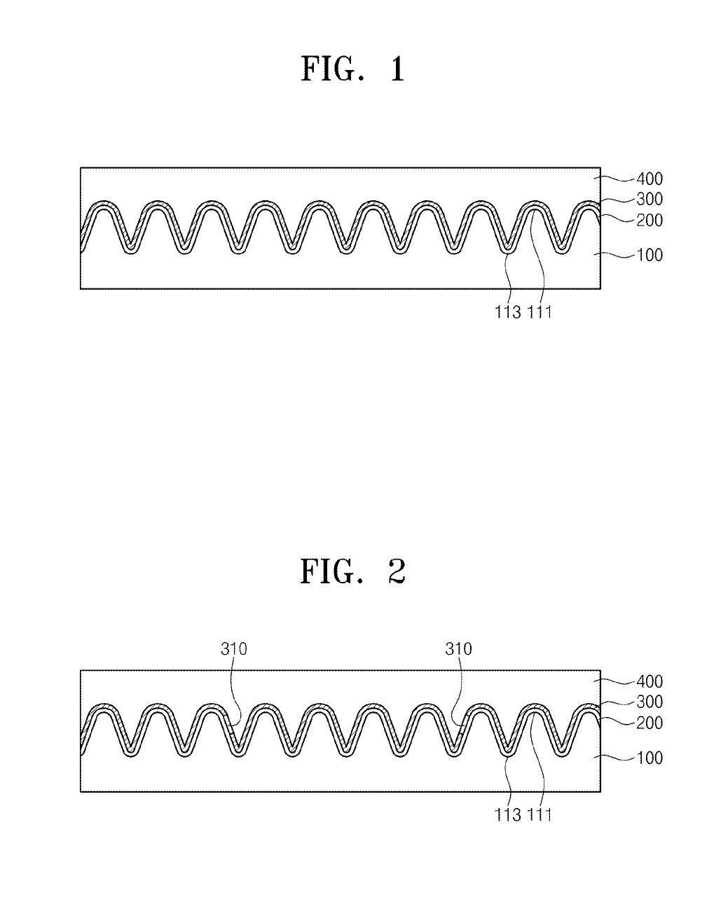

FIG. 1 illustrates a cross-sectional view of a transparent electrode according to a first embodiment of the present inventive concept.

Referring to FIG. 1, the transparent electrode may include a first flexible substrate 100, a graphene film 200, a metal film 300, and a second flexible substrate 400. The first flexible substrate 100 may be a flexible substrate. The flexible substrate may include, for example, polydimethylsiloxane (PDMS) or polyurethane. A top surface of the first flexible substrate 100 may be uneven in a round shape. For example, the top surface of the first flexible substrate 100 may include convex portions 111 and concave portions 113.

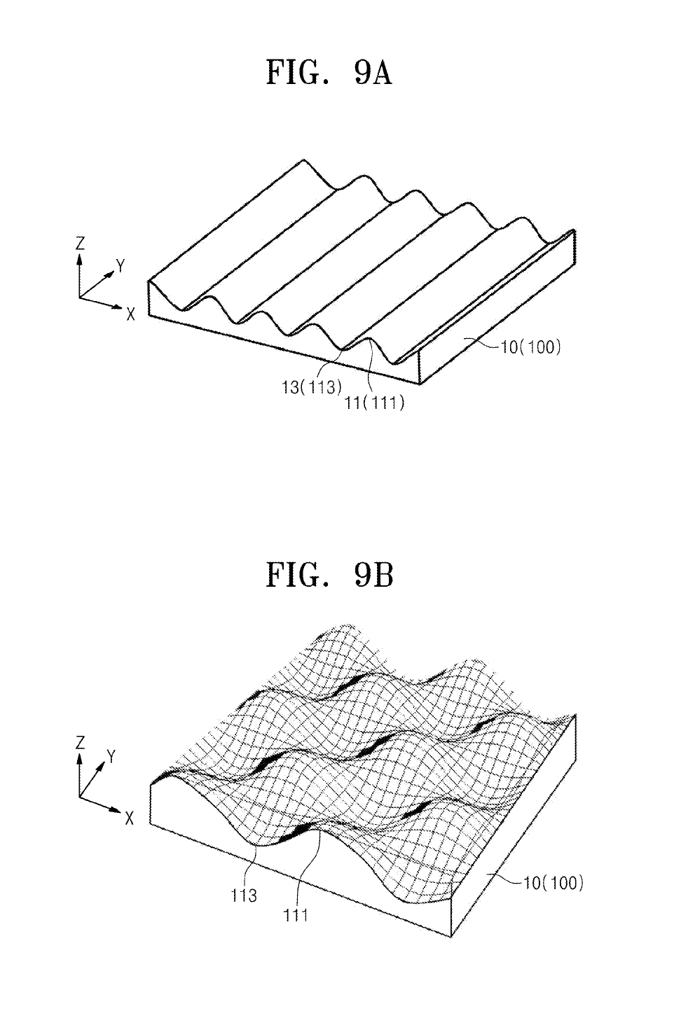

Specifically, referring to FIG. 9A, the convex portions 111 and the concave portions 113 of the first flexible substrate 100 may be alternately and repeatedly arranged in a first direction X. Also, the convex portions 111 and the concave portions 113 may extend in a second direction Y crossing the first direction X.

Referring to FIG. 9B, the convex portions 111 and the concave portions 113 of the first flexible substrate 100 may be alternately and repeatedly arranged in the first and second directions X and Y.

Referring back to FIG. 1, the graphene film 200 may be applied to the first flexible substrate 100. The graphene film 200 is conformally formed on the top surface of the first flexible substrate 100, so that a top surface of the graphene film 200 may have a profile same as the top surface of the first flexible substrate 100. For example, the top surface of the graphene film 200 may be uneven in a round shape.

The graphene film 200 may be coated with a metal film 300. The metal film 300 is conformally formed on the top surface of the graphene film 200, so that a top surface of the metal film 300 may have a profile same as the top surface of the graphene film 200. For example, the top surface of the metal film 300 may be uneven in a round shape. A light may pass through the metal film 300. The metal film 300 may have the thickness of several nanometers. The metal film 300 may include a metal material such as tungsten (W), copper (Cu), aluminum (Al), chromium (Cr), molybdenum (Mo), silver (Ag), or gold (Au).

According to an embodiment of the inventive concept, the metal film 300 is in contact with the graphene film 200 to be able to have a function to complement electrical conductivity of the graphene film 200 with high electrical resistance. Thus, the transparent electrode may have a work function of a desired value.

The metal film 300 may be coated with a second flexible substrate 400. The second flexible substrate 400 may be a flexible substrate. The flexible substrate may include, for example, polydimethylsiloxane (PDMS) or polyurethane. The second flexible substrate 400 may completely cover the top surface of the metal film 300. The second flexible substrate 400 may have a flat top surface. The second flexible substrate 400 may play a role of protecting the top surface of the metal film 300. In addition, the second flexible substrate 400 is disposed opposite the first flexible substrate 100, so that the graphene film 200 and the metal film 300 may be disposed between the first and second flexible substrates 100 and 400. Accordingly, when the first and second flexible substrates 100 and 400 are folded and/or stretched, stress applied to the graphene film 200 and the metal film 300 may be minimized

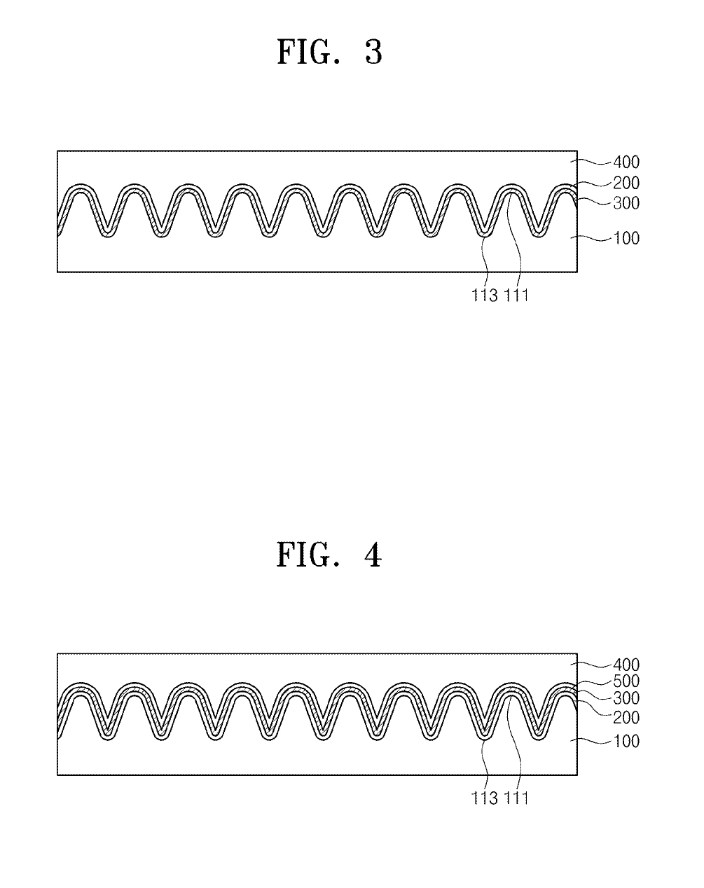

FIG. 2 illustrates a cross-sectional view of a transparent electrode according to a second embodiment of the present inventive concept. For the sake of brevity, the elements and features of this example that are similar to the first embodiment previously shown and described will not be described in much further detail.

Referring to FIG. 2, the metal film 300 may include a crack 310. When the first flexible substrate 100 and the second flexible substrate 400 are folded and/or stretched, the crack 310 may be formed as stress is applied to the metal film 300. As the crack 310 is formed, a current may fail to be transferred through the metal film 300. However, the metal film 300 is in contact with the graphene film 200, thus being able to have a function locally lowering an electrical resistance of the graphene film 200. Accordingly, the metal film 300 may enhance the electrical conductance of the graphene film 200.

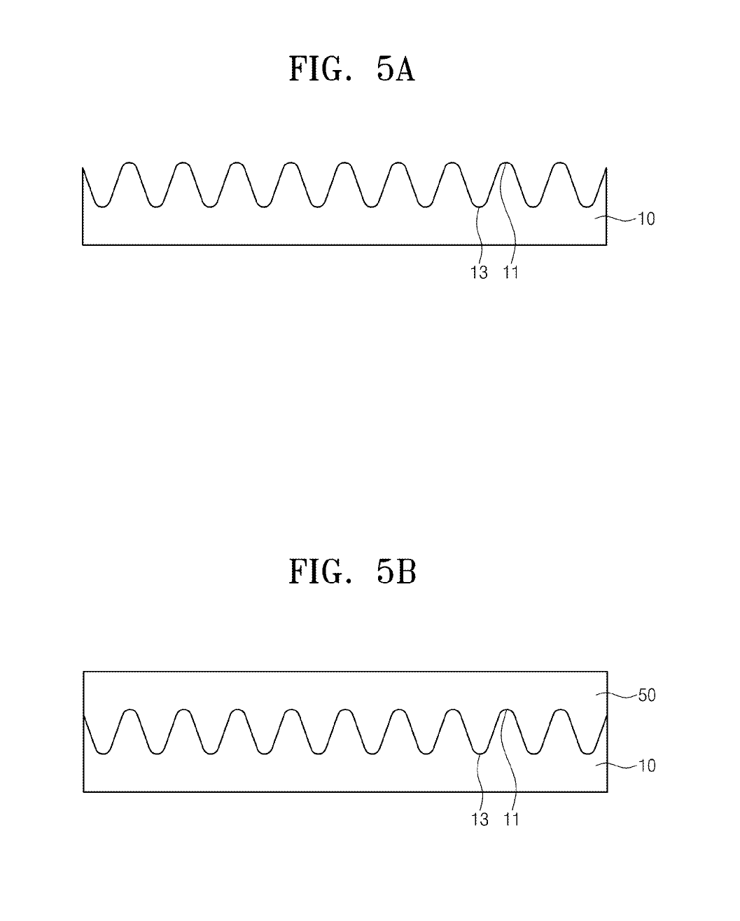

FIG. 3 illustrates a cross-sectional view of a transparent electrode according to a third embodiment of the present inventive concept. For the sake of brevity, the elements and features of this example that are similar to the first and second embodiments previously shown and described will not be described in much further detail.

Unlike the first embodiment, the order in which the graphene film 200 and the metal film 300 are formed may be changed. Referring to FIG. 3, the metal film 300, the graphene film 200, and the second flexible substrate 400 may be sequentially disposed on the first flexible substrate 100.

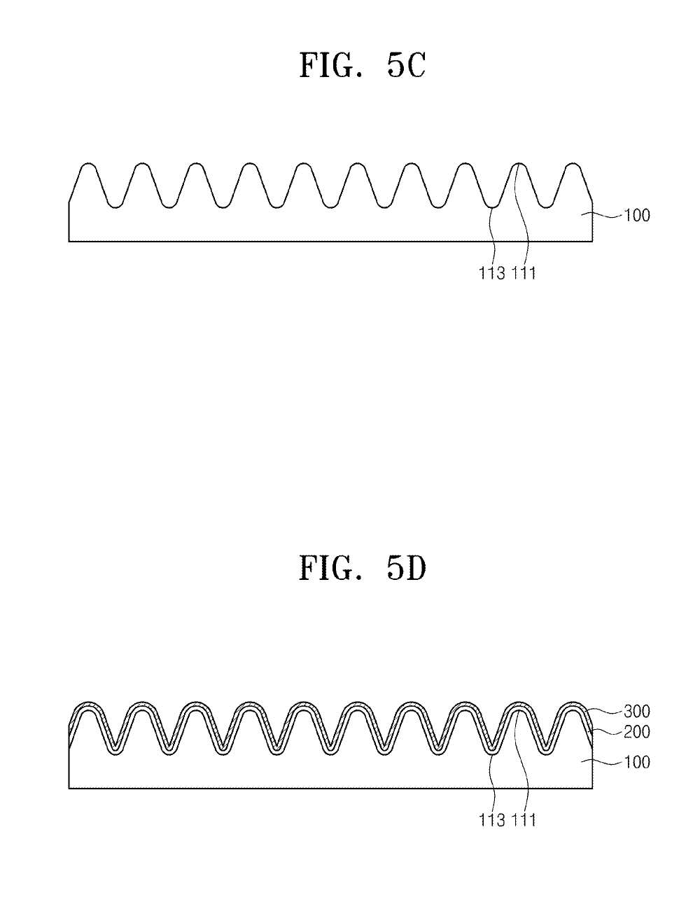

FIG. 4 illustrates a cross-sectional view of a transparent electrode according to a fourth embodiment of the present inventive concept. For the sake of brevity, the elements and features of this example that are similar to the first and third embodiments previously shown and described will not be described in much further detail.

Referring to FIG. 4, the graphene film 200, the metal film 300, and a second graphene film 500 may be sequentially disposed on the first flexible substrate 100. For preventing oxidation of the metal film 300, the second graphene film 500 may be formed on the metal film 300. The second graphene film 500 is conformally formed on the metal film 300, so that a top surface of the second graphene film 500 may have a profile same as the top surface of the metal film 300. For example, the top surface of the second graphene film 500 may be uneven in a round shape. The second flexible substrate 400 may be disposed on the second graphene film 500.

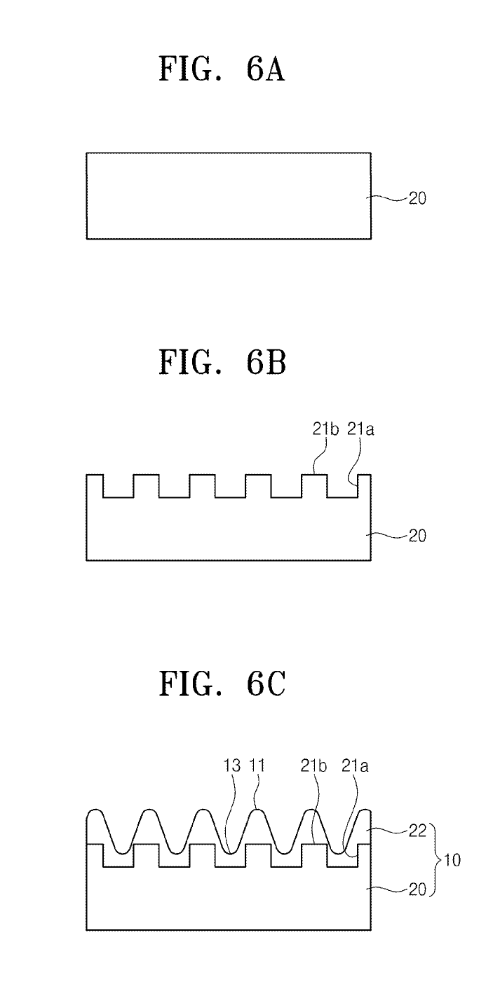

FIGS. 5A to 5D illustrate cross-sectional views of a method of fabricating a transparent electrode according to the first embodiment of the present inventive concept.

Referring to FIG. 5A, a mold structure 10 is formed. A top surface of the mold structure 10 may be uneven in a round shape. Referring to FIG. 9A, the top surface of the mold structure 10 may include concave portions 13 and concave portions 13 may be alternately and repeatedly arranged in a first direction X. The convex portions 11 and the concave portions 13 may extend in a second direction Y crossing the first direction X. Referring to FIG. 9B, the convex portions 11 and the concave portions 13 of the mold structure 10 may be alternately and repeatedly arranged in the first and second directions X and Y. The mold structure 10 may be any one of a silicon substrate, a glass substrate, an insulating substrate, a polymer substrate, and a plastic substrate.

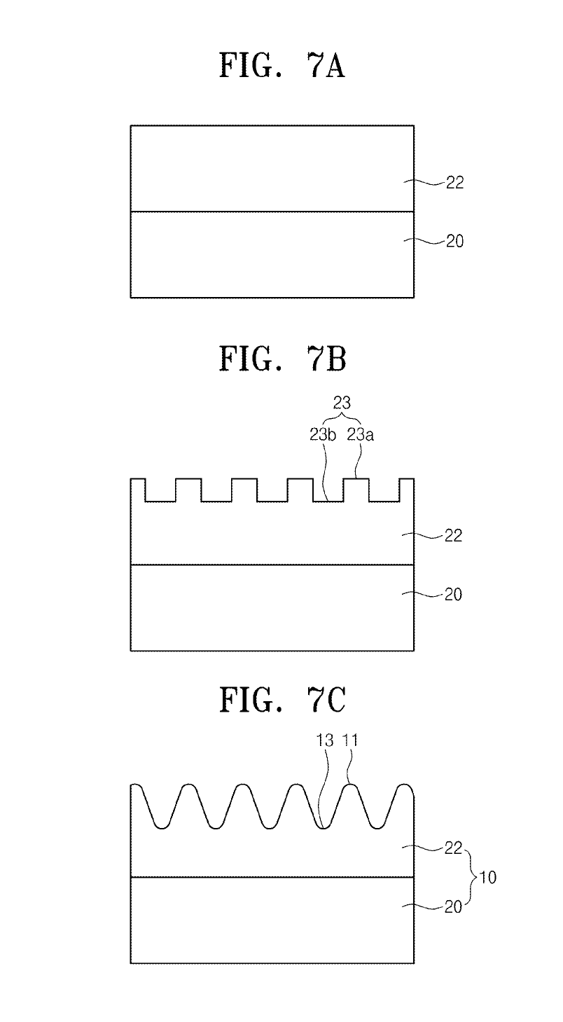

A method of forming the mold structure 10 will be described in detail with reference to FIGS. 6A to 6C, 7A to 7C, and 8A to 8C.

Referring to FIGS. 5B and 5C, a polymer film 50 is formed on the top surface of the mold structure 10. The polymer film 50 may be formed by coating and curing a polymer material on the top surface of the mold structure 10. The polymer film 50 may include, for example, polydimethylsiloxane (PDMS) or polyurethane.

The mold structure 10 is overturned to separate the polymer film 50, so that a first flexible substrate 100 with an uneven surface is formed. The uneven surface of the first flexible substrate 100, formed by contacting the top surface of the mold structure 10 may have a profile same as the top surface of the mold structure 10. The uneven surface of the first flexible substrate 100 may be the top surface of the first flexible substrate 100. For example, the top surface of the first flexible substrate 100 may include convex portions 111 and concave portions 113. Referring to FIG. 9A, the convex portions 111 and the concave portions 113 are alternately and repeatedly arranged in the first direction X, and may extend in the second direction Y crossing the first direction X. Referring to FIG. 9B, the convex portions 111 and the concave portions 113 of the first flexible substrate 100 may be alternately and repeatedly arranged in the first and second directions X and Y.

Referring to FIG. 5D, graphene film 200 may be conformally formed on the top surface of the first flexible substrate 100. The graphene film 200 may be formed on the top surface of the first flexible substrate 100 by a physical method, a chemical method, and a chemical vapor deposition method (CVD). Alternatively, a graphene is grown on a seed film (not shown) and is separated from the seed film, and then is transferred on the top surface of the first flexible substrate 100 to form the graphene film 200. A top surface of the graphene film 200 may have a profile same as the top surface of the first flexible substrate 100.

Metal film 300 may be conformally formed on the top surface of the graphene film 200. The metal film 300 may be deposited, for example, by a physical vapor deposition (e.g., sputtering). The top surface of the metal film 300 may be formed to have a profile same as the top surface of the graphene film 200. The metal film 300 may be formed thin so that a light may pass therethrough. For example, the metal film 300 may be formed to have a thickness of several nanometers. The metal film 300 may include a metal material such as tungsten (W), copper (Cu), aluminum (Al), chromium (Cr), molybdenum (Mo), silver (Ag), or gold (Au).

Referring back to FIG. 1, a second flexible substrate 400 may be formed on the metal film 300. A polymer material is applied to the metal film 300 and is cured to form the second flexible substrate 400. Top surface of the second flexible substrate 400 may have a flat surface.

FIGS. 6A to 6C illustrate cross-sectional views of one example of a method of fabricating a mold structure.

Referring to FIGS. 6A and 6B, a mother substrate 20 is prepared. The mother substrate 20 may be any one of a silicon substrate, a glass substrate, an insulating substrate, a polymer substrate, and a plastic substrate. Trenches 21a may be formed by patterning the mother substrate 20. Projecting surfaces 21b of the mother substrate 20 may be disposed between the trenches 21a. The mother substrate 20 may be patterned by performing any one process of a wet etching and a dry etching.

Referring to FIG. 6C, a photoresist film 22 may be applied to a surface of the mother substrate 20 having trenches 21a formed thereon. The photoresist film 22 may fill the trenches 21a. The photoresist film 22 may be applied to the mother substrate 20 due to a low step coverage property caused by a step difference between a bottom surface of the trenches 21a and the projecting surfaces 2 lb of the mother substrate 20. Accordingly, the top surface of the photoresist film 22 may include convex portions 11 and concave portions 13. The convex portions 11 may be portions of the top surface of the photoresist film 22 applied to the projecting surfaces 21b of the mother substrate 20, and the concave portions 13 may be portions of the top surface of the photoresist film 22 applied to the trenches 21a. The mold structure 10 may include the mother substrate 20 and the photoresist film 22.

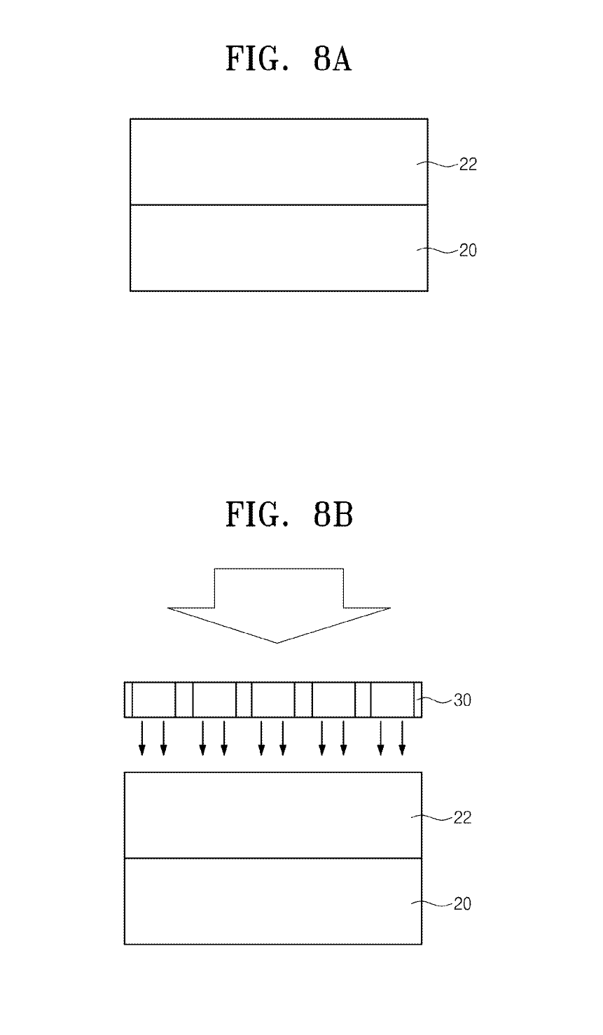

FIGS. 7A to 7C illustrate cross-sectional views of another example of a method of fabricating a mold structure.

Referring to FIGS. 7A and 7B, a photoresist film 22 may be applied to a mother substrate 20. Patterns 23 may be formed by patterning the photoresist film 22. The patterns 23 may be configured by angled convex portions 23a and angled concave portions 23b disposed between the convex portions 23a. The photoresist film 22 may be patterned by performing any one process of a wet etching, a dry etching, and a photolithography process.

Referring to FIG. 7C, a reflow process may be performed on the photoresist film 22. The reflow process may apply a temperature (T>Tg) higher than the glass transition temperature Tg of the photoresist film 22 to the photoresist film 22. By the reflow process, the angled convex portions 23a may be changed into convex portions 11 of a round shape and the angled concave portions 23b may be changed into concave portions 13 of a round shape.

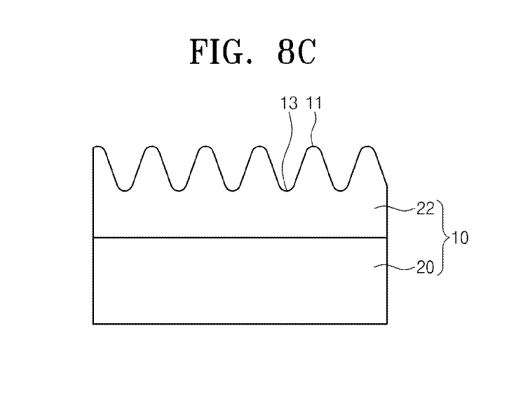

FIGS. 8A to 8C illustrate cross-sectional views of still another example of a method of fabricating a mold structure.

Referring to FIGS. 8A and 8B, a photoresist film 22 may be applied to a mother substrate 20. A grayscale photomask 30 may be disposed on the photoresist film 22. The grayscale photomask 30 may pass different amount of light therethrough by regions. That is, an exposure amount of light may be differentiated by regions by using the grayscale photomask 30.

Referring to FIG. 8C, a development process may be performed on the photoresist film 22. Since the exposure amount of light exposed to the photoresist film 22 is differentiated by using the grayscale photomask 30, an amount of the photoresist film 22 removed when developed may be changed according to a region of the photoresist film 22. For example, the amount of the photoresist film 22 removed in regions having a more exposure amount may be larger than that in regions having a less exposure amount. Accordingly, the top surface of the photoresist film 22 may be formed to have convex portions 11 and concave portions 13. The convex portions 11 of the photoresist film 22 may be regions exposed to a smaller amount of light, and the concave portions 13 of the photoresist film 22 may be regions having exposed to a larger amount of light.

The stretchable transparent electrode according to embodiments of inventive concept may include a graphene film and a metal film disposed on a flexible substrate. The metal film is in contact with the graphene film, thus being able to enhance the electrical conductance of the graphene film with high electrical resistance. Accordingly, a transparent electrode with enhanced electrical conductivity may be provided.

Hereinafter, embodiments of the present invention will be described in detail with reference to the accompanying drawings to fully explain the present invention in such a manner that it may easily be carried out by a person with ordinary skill in the art(hereinafter, ‘those skilled in the art’) to which the present invention pertains. Thus, to the maximum extent allowed by law, the scope of the present invention is to be determined by the broadest permissible interpretation of the following claims and their equivalents, and shall not be restricted or limited by the foregoing detailed description.

What is claimed is:

1. A stretchable transparent electrode comprising:
a first substrate having an uneven surface;
a first conductive film conformally covering the uneven surface of the first substrate to have an uneven top surface;
a second conductive film conformally covering the first conductive film to have an uneven top surface; and
a second substrate covering the second conductive film,
wherein one of the first and second conductive films is a metal film and the other is a graphene film.

2. The stretchable transparent electrode of claim 1, wherein the first conductive film is a graphene film and the second conductive film is a metal film.

3. The stretchable transparent electrode of claim 1, wherein the first conductive film is a metal film and the second conductive film is a graphene film.

4. The stretchable transparent electrode of claim 1, wherein a light passes through the metal film.

5. The stretchable transparent electrode of claim 1, wherein the metal film comprises a crack.

6. The stretchable transparent electrode of claim 2, further comprising a third conductive film conformally covering the second conductive film, wherein the third conductive film is a graphene film.

7. The stretchable transparent electrode of claim 1, wherein the uneven surface of the first substrate comprises convex portions and concave portions, wherein the convex portions and the concave portions are alternately and repeatedly arranged in a first direction and extend in a second direction crossing the first direction.

8. The stretchable transparent electrode of claim 1, wherein the uneven surface of the first substrate comprises convex portions and concave portions, wherein the convex portions and the concave portions are alternately and repeatedly arranged in a first direction and in a second direction crossing the first direction.

9. The stretchable transparent electrode of claim 1, wherein the first and second substrates comprise polydimethylsiloxane PDMS or polyurethane.

10. A method of fabricating a stretchable transparent electrode, the method comprising:
forming a mold structure having an uneven surface;
forming a polymer film on the uneven surface of the mold structure;
separating the polymer film from the mold structure to form a first substrate having an uneven surface;
conformally forming a graphene film on the uneven surface of the first substrate; and
conformally forming a metal film on the graphene film.

11. The method of claim 10, further comprising forming a second substrate on the metal film, wherein the first and second substrates comprise polydimethylsiloxane PDMS or polyurethane.

12. The method of claim 10, further comprising conformally forming a second graphene film on the metal film.

13. The method of claim 10, wherein the forming the mold structure comprises:
preparing a mother substrate;
patterning the mother substrate to form trenches; and
forming a photoresist film filling the trenches on the mother substrate, wherein concave portions of the photoresist film are formed on the trenches and convex portions of the photoresist film are formed on projecting surfaces of the mother substrate due to a step difference between bottom surfaces of the trenches and projecting surfaces of the mother substrate disposed between the trenches.

14. The method of claim 10, wherein the forming the mold structure comprises:
preparing a mother substrate;
forming a photoresist film on the mother substrate;
patterning the photoresist film to form patterns including angled convex portions and angled concave portions; and
performing a reflow process on the photoresist film to change the angled convex portions into rounded convex portions and the angled concave portions into rounded concave portions so as to form a photoresist film having an uneven surface.

15. The method of claim 10, wherein the forming the mold structure comprises:
preparing a mother substrate;
forming a photoresist film on the mother substrate; and
forming the photoresist film curved in a round shape by using a gray scale photomask.
